(19) United States
(12) Patent Application Publication
(10) Pub. No.: US 2023/0320114 A1
(43) Pub. Date: Oct. 5, 2023

(54) ORGANIC ELECTROLUMINESCENT DEVICE

(71) Applicant: BEIJING SUMMER SPROUT TECHNOLOGY CO., LTD., Beijing (CN)

(72) Inventors: Menglan Xie, Beijing (CN); Huiqing Pang, Beijing (CN); Jing Wang, Beijing (CN); Qi Liu, Beijing (CN)

(73) Assignee: BEIJING SUMMER SPROUT TECHNOLOGY CO., LTD., Beijing (CN)

(21) Appl. No.: 18/127,277

(22) Filed: Mar. 28, 2023

(30) Foreign Application Priority Data
Mar. 31, 2022 (CN) 202210322664.4

(51) Int. Cl. H10K 50/11; H10K 50/17

(52) U.S. Cl. CPC H10K 50/11; H10K 50/17; H10K 2101/60

(57) ABSTRACT

Provided is an organic electroluminescent device. The organic electroluminescent device is a bottom-emitting single-layer device. The device has maximum external quantum efficiency EQEₘₐₓ of more than 26%, and has a high roll-off coefficient of greater than or equal to 0.91 at high brightness of 5000 cd/m² or 11500 cd/m².

### CROSS-REFERENCE TO RELATED APPLICATION(S)

This application claims priority to Chinese Patent Application No. 202210322664.4 filed on Mar. 31, 2022, the disclosure of which is incorporated herein by reference in its entirety.

### TECHNICAL FIELD

The present disclosure relates to organic electronic devices, for example, organic light-emitting devices. More particularly, the present disclosure relates to an organic electroluminescent device having a high roll-off coefficient r at high brightness.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

Organic electroluminescent devices have been widely applied to electronic products for daily use. However, in application fields such as lighting, phototherapy and augmented reality (AR), a higher requirement is imposed on the brightness of light-emitting devices, and the efficiency roll-off effect of OLED devices at high brightness, particularly the efficiency roll-off effect of phosphorescent OLED devices at high brightness, is one of the key factors restricting applications thereof. Solving the problem of the efficiency roll-off of the OLED devices, particularly the problem of the efficiency roll-off of the phosphorescent OLED devices, is a subject that scientists have been working on.

There are two main reasons for the efficiency roll-off of the phosphorescent OLED.

The first reason is triplet-triplet annihilation (TTA). A host-guest system is generally used in an emissive layer of the OLED, and the TTA may occur between two guest molecules or between a host molecule and a guest molecule (when the triplet energy level of the host molecule is close to the triplet energy level of the guest molecule), resulting in the efficiency roll-off of the device. There are two main ideas to suppress the efficiency roll-off caused by the TTA. One idea is to reduce the lifetime of excitons to reduce the aggregation of the excitons, and the other idea is to expand the recombination zone (RZ) to reduce the number of excitons per unit volume and reduce the probability of exciton quenching, thereby suppressing the TTA. The recombination zone is closely related to the carrier transport inside the device, that is, the performance of injection, transport and recombination of holes and electrons throughout the device. The performance of the carrier transport not only determines the position and range of the recombination zone, but also significantly affects the characteristics of the efficiency and efficiency roll-off of the device. Therefore, it is very important to research the performance of the carrier transport in the OLED and thus to research the characteristics of the recombination zone, and to accurately control the carrier injection and transport and thus the distribution of the recombination zone can provide better device performance.

Some researches have reported positive effects of expanding the range of the recombination zone on improving the device performance such as the efficiency roll-off and lifetime of the device, for example, double host materials (a p-type host and an n-type host) are used in the emissive layer to achieve carrier balance, or a bipolar host material is directly used to achieve the object of expanding the exciton recombination zone. In a phosphorescent material system, some luminescent materials also play a certain role in the transport of carriers (electrons or holes) of a certain polarity. For example, the patent application EP3690972A1 discloses a method of gradient doping a luminescent material in an emissive layer, which expands the exciton recombination zone and improves lifetime of device. However, current researches are limited to general reports on expanding the exciton recombination zone, and it is not clear how to distribute the exciton recombination zone to effectively suppress the roll-off and obtain better device performance.

The second reason for the efficiency roll-off of the phosphorescent OLED is carrier imbalance. In the OLED, hole mobility is generally three to five orders of magnitude higher than electron mobility, and the quenching effect of excess carriers on excitons results in the efficiency roll-off. It is reported in the document New J. Chem. 38, 650-656 (2014) that the quenching effect of holes on excitons is more significant. At present, however, there are few systematic researches on the carrier balance and the improvement of carrier balance at high brightness. Therefore, how to balance carriers and thus suppress the efficiency roll-off of the OLED device at high brightness still needs in-depth researches.

### SUMMARY

The present disclosure aims to provide a series of organic electroluminescent devices each having a high roll-off coefficient r at high brightness to solve at least part of the above-mentioned problems. The organic electroluminescent device is a bottom-emitting single-layer device, which has maximum external quantum efficiency of more than 26%, and has a high roll-off coefficient of greater than or equal to 0.91 at high brightness of 5000 cd/m² or 11500 cd/m².

According to an embodiment of the present disclosure, disclosed is an organic electroluminescent device, which is a bottom-emitting single-layer device and comprises an anode, a cathode and at least one emissive layer disposed between the anode and the cathode, wherein the at least one emissive layer comprises at least one luminescent material;
when brightness is L₁, the organic electroluminescent device has maximum external quantum efficiency EQEₘₐₓ, wherein the EQEₘₐₓ≥26%;
when the brightness is L₂, the organic electroluminescent device has external quantum efficiency EQE₂, wherein EQE₂/EQEₘₐₓ=90%, L₁<L₂, and L₂>5000 cd/m²;
when the brightness is L₃, the organic electroluminescent device has external quantum efficiency EQE₃ and a roll-off coefficient r=EQE₃/EQEₘₐₓ, wherein the roll-off coefficient r≥0.91; and
the at least one luminescent material has a peak wavelength λₘₐₓ, wherein 500 nm<λₘₐₓ<700 nm; when 600 nm<λₘₐₓ<700 nm, the brightness L₃=5000 cd/m², and when 500 nm<λₘₐₓ≤600 nm, the brightness L₃=11500 cd/m².

In a practical application, for a red light OLED device, it is required to have a small efficiency roll-off effect (a high roll-off coefficient r) at brightness of more than 3000 cd/m², and for a green light OLED device, it is required to have a small efficiency roll-off effect (a high roll-off coefficient r) at brightness of more than 10000 cd/m². Therefore, it is limited herein that when the peak wavelength λₘₐₓ of the at least one luminescent material is between 600 nm (including the endpoint) and 700 nm (excluding the endpoint) (red light material), the brightness L₃ is 5000 cd/m², and when the peak wavelength λₘₐₓ of the at least one luminescent material is between 500 nm (excluding the endpoint) and 600 nm (excluding the endpoint) (green light material), the brightness L₃ is 11500 cd/m².

According to an embodiment of the present disclosure, the EQEₘₐₓ≥27%.

According to an embodiment of the present disclosure, the EQEₘₐₓ≥28%.

According to an embodiment of the present disclosure, L₂≥6000 cd/m².

According to an embodiment of the present disclosure, L₂≥7000 cd/m².

According to an embodiment of the present disclosure, the device comprises a hole injection layer (HIL) having a conductivity of greater than 50×10⁻⁵ S/m and less than 140×10⁻⁵ S/m.

According to an embodiment of the present disclosure, the HIL has a conductivity of greater than 60×10⁻⁵ S/m and less than 120×10⁻⁵ S/m.

According to an embodiment of the present disclosure, when the organic electroluminescent device reaches EQEₘₐₓ, the exciton recombination zone is located in the emissive layer on the side close to the anode within a region of less than 50% of the emissive layer thickness.

According to an embodiment of the present disclosure, when the organic electroluminescent device reaches EQEₘₐₓ, the exciton recombination zone is located in the emissive layer on the side close to the anode within a region of less than 30% of the emissive layer thickness.

According to an embodiment of the present disclosure, when the organic electroluminescent device reaches EQEₘₐₓ, the exciton recombination zone is located in the emissive layer on the side close to the anode within a region of less than 25% of the emissive layer thickness.

According to an embodiment of the present disclosure, the at least one luminescent material has an exciton lifetime of less than 2 microseconds.

According to an embodiment of the present disclosure, the at least one luminescent material has an exciton lifetime of less than 1.5 microseconds.

According to an embodiment of the present disclosure, the at least one emissive layer further comprises at least one host material, wherein a difference between a triplet energy level of the at least one host material and a triplet energy level of the at least one luminescent material is ΔT₁, and the ΔT₁≥0.3 eV.

According to an embodiment of the present disclosure, the ΔT₁≥0.4 eV.

According to an embodiment of the present disclosure, the ΔT₁≥0.5 eV.

According to an embodiment of the present disclosure, the roll-off coefficient r≥0.95.

According to an embodiment of the present disclosure, the roll-off coefficient r≥0.97.

According to an embodiment of the present disclosure, the at least one luminescent material is a phosphorescent material.

The organic electroluminescent device disclosed in the present disclosure is a bottom-emitting single-layer organic electroluminescent device, which has maximum external quantum efficiency of more than 26%, and has a high roll-off coefficient of greater than or equal to 0.91 at high brightness of 5000 cd/m² or 11500 cd/m².

### BRIEF DESCRIPTION OF DRAWINGS

FIG. 1 is a schematic diagram of structures of part of a device when a probe layer is distributed at positions of different thicknesses of an emissive layer.

FIG. 2 is a trend graph illustrating a relationship between an exciton fraction and a position of a probe layer of Example 1, Comparative Example 1 and Comparative Example 2.

FIG. 3 is a normalized EQE-L curve graph of Example 1, Comparative Example 1, Comparative Example 2 and Comparative Example 3.

FIG. 4 is a normalized EQE-L curve graph of Example 2 and Comparative Example 4.

FIG. 5 is a normalized EQE-L curve graph of Example 3, Comparative Example 5 and Comparative Example 6.

FIG. 6 is a normalized EQE-L curve graph of Example 5 and Comparative Example 7.

FIG. 7 is a schematic diagram of an organic light-emitting apparatus that may include an organic electroluminescent device of the present disclosure.

FIG. 8 is a schematic diagram of another organic light-emitting apparatus that may include an organic electroluminescent device of the present disclosure.

### DETAILED DESCRIPTION

OLEDs can be fabricated on various types of substrates such as glass, plastic, and metal foil. FIG. 7 schematically shows an organic light-emitting apparatus 100 without limitation. The figures are not necessarily drawn to scale. Some of the layers in the figures can also be omitted as needed. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

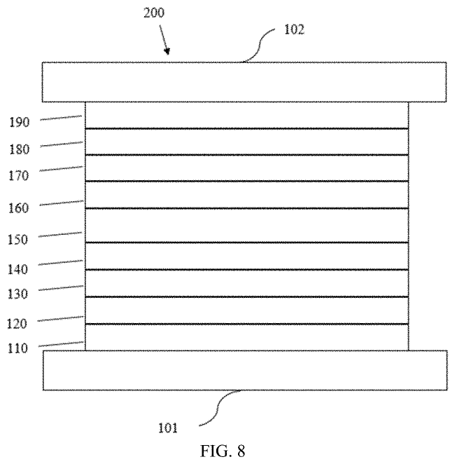

An OLED can be encapsulated by a barrier layer. FIG. 8 schematically shows an organic light emitting device 200 without limitation. FIG. 8 differs from FIG. 7 in that the organic light emitting device include a barrier layer 102, which is above the cathode 190, to protect it from harmful species from the environment such as moisture and oxygen. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (ΔE_{S-T}). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

As used herein, “bottom-emitting OLED device” refers to an OLED device that emits light from one side of a substrate.

As used herein, the term “OLED light-emitting panel” includes a substrate, an anode layer, a cathode layer, one or more organic layers disposed between the anode layer and the cathode layer, an encapsulation layer and at least one anode contact and at least one cathode contact extending outside of the encapsulation layer for external access.

As used herein, the term “encapsulation layer” may be a thin film encapsulation with a thickness of less than 100 micrometers, which includes one or more thin films directly disposed on the device, or may be a cover glass gluing on the substrate.

As used herein, the term “peak wavelength λₘₐₓ” refers to a wavelength corresponding to the maximum intensity of an electroluminescence (EL) spectrum in the OLED device.

The term “single-layer device” refers to a device which includes only one light-emitting unit between the cathode and the anode, where the one light-emitting unit generally includes at least one emissive layer, one hole transport layer and one electron transport layer. On this basis, one or more of a hole injection layer, an electron injection layer, a hole blocking layer and an electron blocking layer may optionally be included. It is to be noted that although the single-layer device has only one light-emitting unit, the one light-emitting unit may include a plurality of emissive layers, for example, the one light-emitting unit may include one yellow light emissive layer and one blue light emissive layer, but each light-emitting unit may include only one pair of hole transport layer and electron transport layer.

The term “efficiency roll-off” or “roll-off” refers to a phenomenon that after the efficiency of the OLED device reaches a peak value, the efficiency of the OLED device decays as the brightness increases. In the present application, a ratio of EQE at particular brightness to peak EQE is used for evaluating the roll-off of the device. The roll-off coefficient r of the device is defined by the following formula:

$$r = \frac{E Q {E}_{3}}{E Q {E}_{max}} .$$

The roll-off coefficient formula includes parameters EQEₘₐₓ and EQE₃, wherein EQEₘₐₓ is maximum EQE that the device can achieve, and EQE₃ is the EQE of the device at particular brightness L₃. When the peak wavelength λₘₐₓ of the luminescent material in the emissive layer of the device is between 600 nm (including the endpoint) and 700 nm (excluding the endpoint), the brightness L₃ is 5000 cd/m², and when the peak wavelength λₘₐₓ of the luminescent material is between 500 nm (excluding the endpoint) and 600 nm (excluding the endpoint), the brightness L₃ is 11500 cd/m². Apparently, the closer EQE₃ and EQEₘₐₓ are, the larger r is, which means that the smaller the roll-off of the device at high brightness is. Since the efficiency roll-off in the OLED is almost inevitable, r is generally less than 1, and the larger the roll-off coefficient is, the closer r is to 1, which indicates that the efficiency can be maintained at a high level in this brightness interval, that is, the smaller the roll-off effect is.

The term “conductivity” refers to that in a high vacuum (10⁻⁶ Torr) environment, the to-be-tested sample material is deposited on a test substrate pre-prepared with aluminum electrodes to form a to-be-tested region with a thickness of 100 nm, a length of 6 mm and a width of 1 mm, then the resistance value of the to-be-tested region is obtained by applying a voltage to the electrodes and measuring a current at room temperature, and then the conductivity of the given thin film is calculated according to the Ohm's law and the geometric dimensions. It is to be noted that when the to-be-tested material layer is formed by doping two or more materials, even if the structures of the two materials remain unchanged, the conductivity of the to-be-tested film can be adjusted to some extent by adjusting a doping proportion. For the hole injection layer (HIL), the conductivity is an important indicator reflecting the hole injection ability. For example, as shown in Table 1, when the doping proportion of HI1 is 3%, the conductivity of the HIL is 24×10⁻⁵ S/m, and when the doping proportion is increased to 10%, the conductivity is increased to 48×10⁻⁵ S/m. The conductivity of the HIL (the hole injection layer) reflects the amount of hole injection to some extent. The higher the conductivity is, the more the holes are injected, otherwise the less. The selection of an appropriate p-type doped material and the adjustment of a doping proportion of the p-type doped material can control the conductivity of the thin film and adjust the amount of hole injection of the HIL.

The term “doping proportion” refers to the percentage of a material in an organic thin film to the total mass of the thin film.

The term “exciton lifetime” refers to the lifetime of the luminescent material in excited state (in the case of a phosphorescent material, it refers to a phosphorescent lifetime). In the present application, the exciton lifetime is measured by using a transient fluorescence spectrometer Deltapro produced by HORIBA, Ltd. A specific method is as follows: a sample is prepared into a solution with a concentration of 5×10⁻⁵ mol/L by using toluene, nitrogen is introduced into the prepared solution for oxygen removal for 10 minutes, and the sample is excited and tested by using a light source of Spectra LED at room temperature (298 K) and analyzed by using a fitting method to obtain lifetime data.

The term “exciton fraction” refers to a ratio of the number of excitons at a certain position in the emissive layer to the total number of excitons in the emissive layer. The exciton fraction reflects how much exciton recombination occurs within a diffusion length of a probe layer and can be used for characterizing a relative relationship of the exciton distribution of the device.

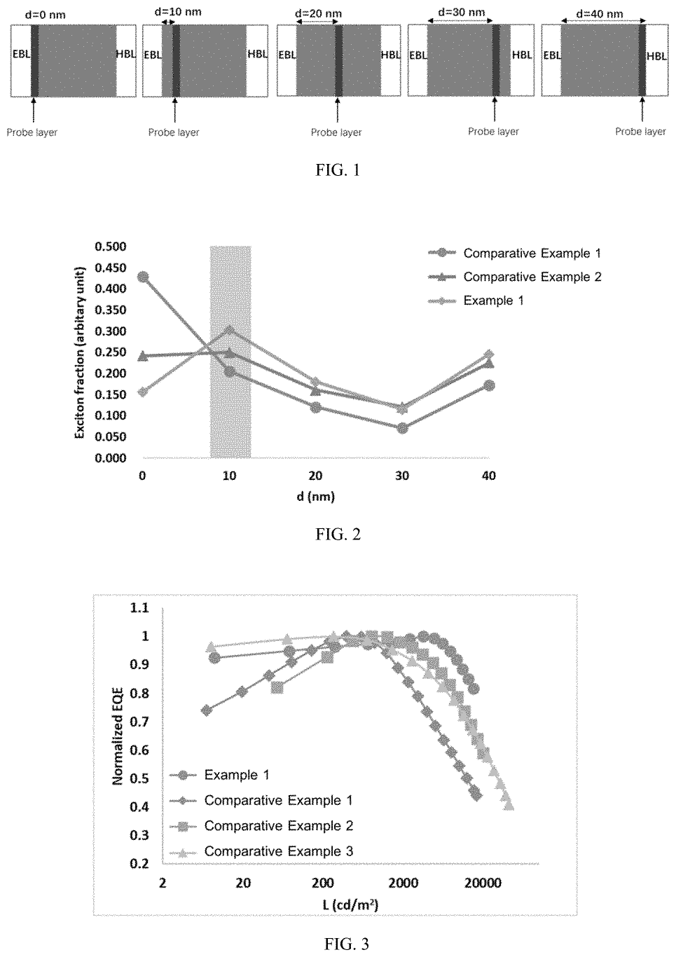

The exciton fraction can be calculated according to the data of the EL spectrum. FIG. 1 is a schematic diagram of device structures when a probe layer is located in an emissive layer at different distances from an interface between the emissive layer (EML) and the EBL. d=0 nm indicates that the probe layer is disposed in the emissive layer at a distance of 0 nm from the EML/EBL interface (at the interface between the EML and the EBL), d=10 nm indicates that the probe layer is disposed in the emissive layer at a distance of 10 nm from the EML/EBL interface, and so on. FIG. 1 is a schematic diagram of a probe layer distributed at d=0 nm, d=10 nm, d=20 nm, d=30 nm and d=40 nm, respectively. The probe layer is composed of a host material H-2

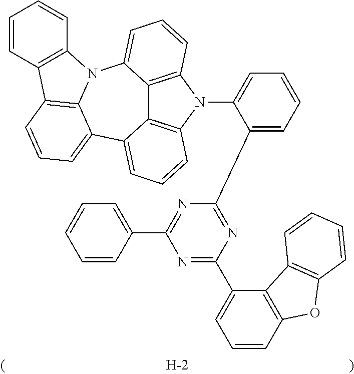

and a deep red luminescent material

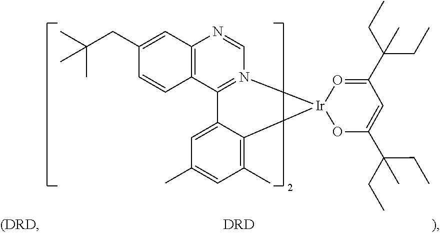

where DRD has a doping proportion of 1% and a peak wavelength of 657 nm. DRD can be effectively distinguished from D-1 with a peak wavelength of 619 nm in Example 1, and the exciton fraction can be calculated according to peak wavelength intensity of DRD in the electroluminescence (EL) spectrum of the device with the probe layer. For example, if the probe layer is located at d=0 nm, d=0 nm indicates that the distance between the probe layer and the interface between the emissive layer and the EBL is 0 nm, that is, the probe layer is located between the emissive layer and the EBL, and the exciton fraction can be calculated as follows: an integrated area of a spectrum on a wavelength of a device without a probe layer is subtracted from an integrated area of the spectrum on the wavelength of the device with the probe layer at d=0 nm, and then divided by a sum of differences that the integrated area of the spectrum of the device without the probe layer is subtracted from integrated areas of spectrums with probe layers located at d=0 nm, d=10 nm, d=20 nm, d=30 nm and d=40 nm. The formula is as follows:

$${Exciton Fraction \vert}_{d = i} = \frac{\int {EL}_{i} d λ - \int {EL}_{B} d λ}{{\sum }_{i}^{0 - 40} ( \int {EL}_{i} d λ - \int {EL}_{B} d λ )} .$$

where i is 0, 10, 20, 30 or 40, ELᵢ refers to the EL spectrum of the device with the probe layer at the position d=i, EL_{B} refers to the EL spectrum of the device without the probe layer, and λ is the wavelength.

Since the exciton distribution may move with the variation in brightness, in the present application, the exciton fractions of d=0 nm, d=10 nm, d=20 nm, d=30 nm and d=40 nm are calculated when the brightness is L₁ (EQEₘₐₓ), respectively, and a trend graph illustrating that exciton fractions of Example 1, Comparative Example 1 and Comparative Example 2 vary with the variation in position d as shown in FIG. 2 is drawn. In Example 1, the exciton fraction reaches a maximum value when d=10 nm, that is, the exciton fraction reaches a peak value when d=10 nm.

As used herein, the term “triplet energy level” refers to energy corresponding to a highest energy feature discernible in a phosphorescence spectrum of a given material. The highest energy feature is not necessarily a peak having greatest intensity in the phosphorescence spectrum, but may be a local maximum value of a clear shoulder on a high energy side of such a peak. The triplet energy level T₁ is calculated according to the following formula:

T₁=1240/λ.

A test method for the wavelength λ is as follows: a low-temperature photoluminescence (PL) spectrum test is performed by using a fluorescence spectrophotometer LENGGUANG F98 produced by SHANGHAI LENGGUANG TECH. CO., LTD, and a low-temperature photoluminescence spectrum of a related compound is measured. A to-be-tested sample is dissolved with anhydrous 2-methyltetrahydrofuran and prepared into a solution with a concentration of 10⁻⁵ mol/L. The sample is loaded into a low-temperature sample tube and placed into a Dewar flask loaded with liquid nitrogen. Then, an excitation wavelength is selected according to a property of the corresponding compound, the low-temperature (77 K) photoluminescence spectrum of the compound is measured, and wavelength (λ) data corresponding to a peak of characteristic intensity is read directly from the spectrum.

In the examples of the device, the characteristics of the device were also tested using conventional equipment in the art (including, but not limited to, evaporator produced by ANGSTROM ENGINEERING, optical testing system produced by SUZHOU FATAR, life testing system produced by SUZHOU FATAR, and ellipsometer produced by BEIJING ELLITOP, etc.) by methods well-known to the persons skilled in the art. As the persons skilled in the art are aware of the above-mentioned equipment use, test methods and other related contents, the inherent data of the sample can be obtained with certainty and without influence, so the above related contents are not further described in this patent.

### EXAMPLES

Hereinafter, the present disclosure is described in more detail with reference to the following examples. Apparently, the following examples are only for the purpose of illustration and not intended to limit the scope of the present disclosure. Based on the following examples, those skilled in the art can obtain other examples of the present disclosure by conducting improvements on these examples.

For the problem of efficiency roll-off of a phosphorescent device, several schemes that can effectively reducing the roll-off of the OLED device at high brightness have been developed in the present application through in-depth researches.

1. Carrier injection, especially hole injection, is adjusted.

Ideally, when carriers reach a perfect balance, pairs of electrons and holes combine in the emissive layer to emit light. In practice, however, holes and electrons have different mobility, and in general, hole mobility of an organic material is three to five orders of magnitude higher than electron mobility, resulting in carrier imbalance in the emissive layer. Moreover, excess holes may exacerbate exciton quenching. Our researches have found that a doping technology using a p-dopant material can more easily adjust the injection amount of holes from the anode to the HIL so that the carriers can reach a better balance in the emissive layer. The amount of hole injection can be indirectly characterized by the conductivity of the HIL.

While, the amount of carrier injection may directly affect the position and range of the recombination zone. Our researches on the recombination zone have found that when the conductivity of the HIL is within a range of 50×10⁻⁵ S/m to 140×10⁻⁵ S/m, the peak value of the exciton fraction occurs at the brightness of L₁, and the recombination zone is located in the emissive layer on the side close to the anode within a region of less than 50% of the emissive layer thickness, the efficiency roll-off of the device in this case can be more effectively suppressed.

2. Selecting a phosphorescent material with a short exciton lifetime can effectively reduce the probability of exciton quenching.

Since the phosphorescent material generally has a relatively long exciton lifetime, exciton density in the emissive layer is easily caused to be too large, and the probability of exciton quenching is increased, thereby exacerbating the roll-off of the device efficiency at high brightness. Our researches on phosphorescent materials with different exciton lifetimes have found that when the exciton lifetime is less than 2 microseconds, the roll-off of the device can be effectively suppressed.

3. An appropriate host material is selected for use with the luminescent material.

For efficient energy transfer, the triplet of the host material is generally higher than the triplet of the luminescent material. When the triplet energy levels of the two materials are not significantly different, the triplet energy of the luminescent material may be reversely transmitted to the host material. In particular, at a high current density, the probability of this reverse transfer may increase significantly, resulting in serious roll-off of the device at a high current density. Therefore, our researches on a combination of host materials with different triplet energy levels and the luminescent material have found that when a difference between the triplet of the host material and the triplet energy level of the luminescent material is ≥0.3 eV, the efficiency roll-off of the device can be effectively suppressed.

4. Through a combination of the above schemes, the roll-off of the device can be suppressed more effectively, a device with a roll-off coefficient of 0.99 is obtained, the maximum efficiency EQEₘₐₓ of the device reaches 33.5%, and when the efficiency decays to 90% of EQEₘₐₓ, the brightness L₂ of the device reaches 12,000 cd/m².

Examples 1 to 4 and Comparative Examples 1 to 6 are red light OLED devices.

Example 5 and Comparative Example 7 are green light OLED devices.

### Example 1

The preparation process of Example 1 is described below. A glass substrate having an indium tin oxide (ITO) anode (with a thickness of 1200 Å) was cleaned, treated with UV ozone and oxygen plasma, dried in a nitrogen-filled glovebox to remove moisture, and then mounted on a substrate holder and placed in a vacuum chamber. Organic layers were sequentially deposited through vacuum thermal evaporation on the ITO anode at a rate of 0.01-10 Å/s and at a vacuum degree of about 10⁻⁶ Torr. Compound HT1 and Compound HI1 were deposited to form a hole injection layer (HIL), where Compound HI1 had a doping proportion of 23%, and the HIL had a thickness of 100 Å. Compound HT1 was deposited for use as a hole transport layer (HTL) with a thickness of 400 Å. Compound EB1 was deposited for use as an electron blocking layer (EBL) with a thickness of 50 Å. A red light dopant Compound D-1 and a red light host compound H-1 were co-deposited to form a red light emissive layer (EML) with a thickness of 400 Å, where the red light dopant Compound D-1 had a doping proportion of 3%. Compound HB was deposited for use as a hole blocking layer (HBL) with a thickness of 50 Å. On the HBL, Compound ET and 8-hydroxyquinolinolato-lithium (Liq) were co-deposited for use as an electron transport layer (ETL) with a thickness of 350 Å, where Liq accounted for 60% of a total weight of the ETL. On the ETL, Liq was deposited for use as an electron injection layer with a thickness of 10 Å. Finally, the substrate was transferred to a metal bin, and Al was deposited for use as a cathode with a thickness of 1200 Å. The device was transferred back to the glovebox and encapsulated with a glass lid to complete the device.

### Example 2

The preparation method in Example 2 was the same as that in Example 1, except that Compounds HT2 and HI2 were deposited to form the HIL, where HI2 had a doping proportion of 3%, HT1 was replaced with Compound HT2 in the HTL, and D-1 was replaced with D-2 in the emissive layer as the luminescent material.

### Example 3

The preparation method in Example 3 was the same as that in Example 2, except that Compound HATCN was deposited to form the HIL, and Compounds H-2 and D-3 were co-deposited to form the emissive layer, where D-3 had a doping proportion of 2%.

### Example 4

The preparation method in Example 4 was the same as that in Example 1, except that Compounds H-2 and D-2 were co-deposited to form the emissive layer, where D-2 had a doping proportion of 3%.

### Example 5

The preparation method in Example 5 was the same as that in Example 1, except that Compound HATCN was deposited to form the HIL (with a thickness of 100 Å), Compound HT2 was deposited to form the HTL (with a thickness of 350 Å), EB2 was deposited to form the EBL (with a thickness of 50 Å), and Compounds EB2, H-3 and D-4 were co-deposited to form the EML (with a thickness of 400 Å), where a doping ratio of Compounds EB2, H-3 and D-4 was 47:47:6.

### Comparative Example 1

The preparation method in Comparative Example 1 was the same as that in Example 1, except that the doping proportion of Compound HI1 in the HIL was adjusted to 3%.

### Comparative Example 2

The preparation method in Comparative Example 2 was the same as that in Example 1, except that the doping proportion of Compound HI1 in the HIL was adjusted to 10%.

### Comparative Example 3

The preparation method in Comparative Example 3 was the same as that in Example 1, except that Compounds HT1 and HI3 were co-deposited to form the HIL, where HI3 had a doping proportion of 3%.

### Comparative Example 4

The preparation method in Comparative Example 4 was the same as that in Example 2, except that in the emissive layer, Compound D-2 was replaced with Compound D-5 as the luminescent material.

### Comparative Example 5

The preparation method in Comparative Example 5 was the same as that in Example 3, except that in the emissive layer, Compound H-2 was replaced with Compound H-4 as the host material.

### Comparative Example 6

The preparation method in Comparative Example 6 was the same as that in Example 3, except that in the emissive layer, Compound H-2 was replaced with Compound H-5 as the host material.

### Comparative Example 7

The preparation method in Comparative Example 7 was the same as that in Example 5, except that in the emissive layer, Compound D-4 was replaced with Compound D-6 as the luminescent material.

Detailed structures and thicknesses of functional layers of the devices are shown in the following table. A layer using more than one material is obtained by doping different compounds at their weight ratio as recorded.

TABLE 1
Structures of part of functional layers of devices

| Device No. | HIL | HTL | EBL | EML | HBL |
|---|---|---|---|---|---|
| Example 1 | Compound | Compound | Compound | Compound | Compound |
| | HT1:HI1 | HT1 | EB1 | H-1:Compound D-1 | HB |
| | (77:23) (100 Å) | (400 Å) | (50 Å) | (97:3) (400 Å) | (50 Å) |
| Example 2 | HT2:HI2 | Compound | Compound | Compound | Compound |
| | (97:3) (100 Å) | HT2 | EB1 | H-1:Compound D-2 | HB |
| | | (400 Å) | (50 Å) | (97:3) (400 Å) | (50 Å) |
| Example 3 | Compound | Compound | Compound | Compound | Compound |
| | HATCN | HT2 | EB1 | H-2:Compound D-3 | HB |
| | (100 Å) | (400 Å) | (50 Å) | (98:2) (400 Å) | (50 Å) |
| Example 4 | Compound | Compound | Compound | Compound | Compound |
| | HT1:HI1 | HT1 | EB1 | H-2:Compound D-2 | HB |
| | (77:23) (100 Å) | (400 Å) | (50 Å) | (97:3) (400 Å) | (50 Å) |
| Example 5 | Compound | Compound | Compound | Compound | Compound |
| | HATCN | HT2 | EB2 | EB2:Compound | HB |
| | (100 Å) | (350 Å) | (50 Å) | H-3:Compound D-4 | (50 Å) |
| | | | | (47:47:6) (400 Å) | |
| Comparative | Compound | Compound | Compound | Compound | Compound |
| Example 1 | HT1:HI1 | HT1 | EB1 | H-1:Compound D-1 | HB |
| | (97:3) (100 Å) | (400 Å) | (50 Å) | (97:3) (400 Å) | (50 Å) |
| Comparative | Compound | Compound | Compound | Compound | Compound |
| Example 2 | HT1:HI1 | HT1 | EB1 | H-1:Compound D-1 | HB |
| | (90:10) (100 Å) | (400 Å) | (50 Å) | (97:3) (400 Å) | (50 Å) |
| Comparative | Compound | Compound | Compound | Compound | Compound |
| Example 3 | HT1:HI3 | HT1 | EB1 | H-1:Compound D-1 | HB |
| | (97:3) (100 Å) | (400 Å) | (50 Å) | (97:3) (400 Å) | (50 Å) |
| Comparative | Compound | Compound | Compound | Compound | Compound |
| Example 4 | HT2:HI2 | HT2 | EB1 | H-1:Compound D-5 | HB |
| | (97:3) (100 Å) | (400 Å) | (50 Å) | (97:3) (400 Å) | (50 Å) |
| Comparative | Compound | Compound | Compound | Compound | Compound |
| Example 5 | HATCN | HT2 | EB1 | H-4:Compound D-3 | HB |
| | (100 Å) | (400 Å) | (50 Å) | (98:2) (400 Å) | (50 Å) |
| Comparative | Compound | Compound | Compound | Compound | Compound |
| Example 6 | HATCN | HT2 | EB1 | H-5:Compound D-3 | HB |
| | (100 Å) | (400 Å) | (50 Å) | (98:2) (400 Å) | (50 Å) |
| Comparative | Compound | Compound | Compound | Compound | Compound |
| Example 7 | HATCN | HT2 | EB2 | EB2:Compound | HB |
| | (100 Å) | (350 Å) | (50 Å) | H-3:Compound D-6 | (50 Å) |
| | | | | (47:47:6) (400 Å) | |

The structures of the materials used in the devices are shown as follows:

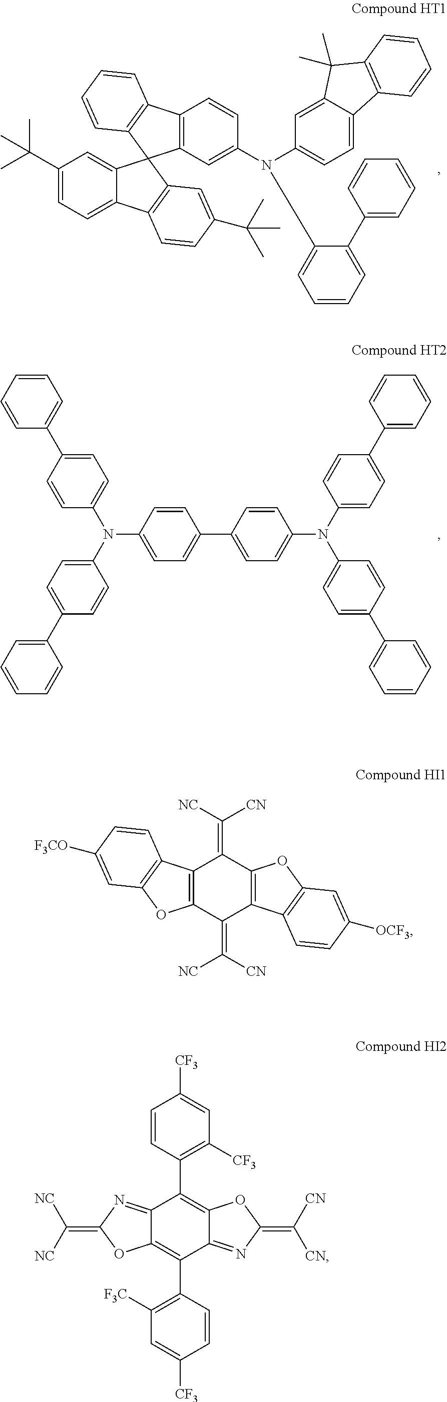 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; N#CC(C#N)=c1c2oc3cc(OC(F)(F)F)ccc3c2c(=C(C#N)C#N)c2oc3cc(OC(F)(F)F)ccc3c12 ; N#CC(C#N)=c1nc2c(-c3ccc(C(F)(F)F)cc3C(F)(F)F)c3oc(=C(C#N)C#N)nc3c(-c3ccc(C(F)(F)F)cc3C(F)(F)F)c2o1]

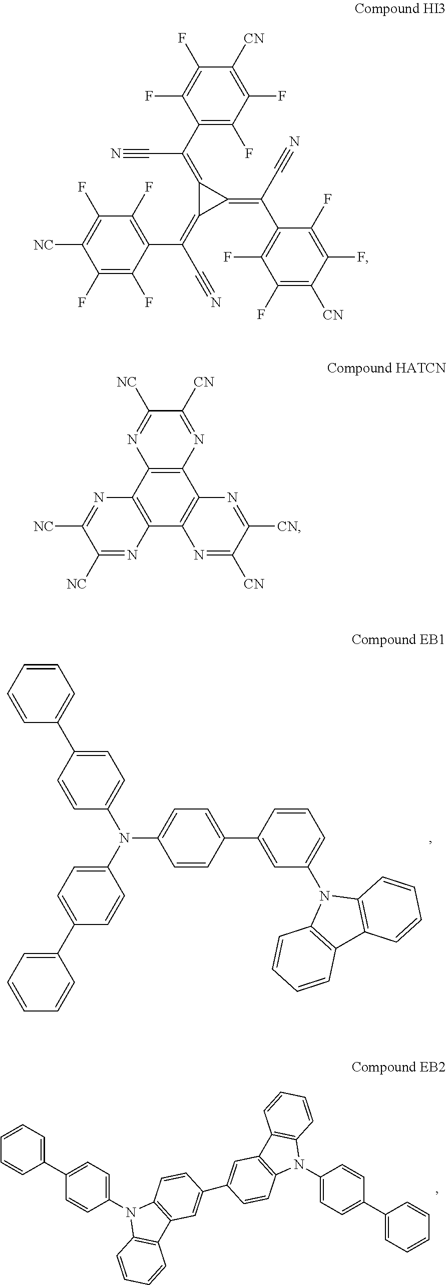 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4cccc(-n5c6ccccc6c6ccccc65)c4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

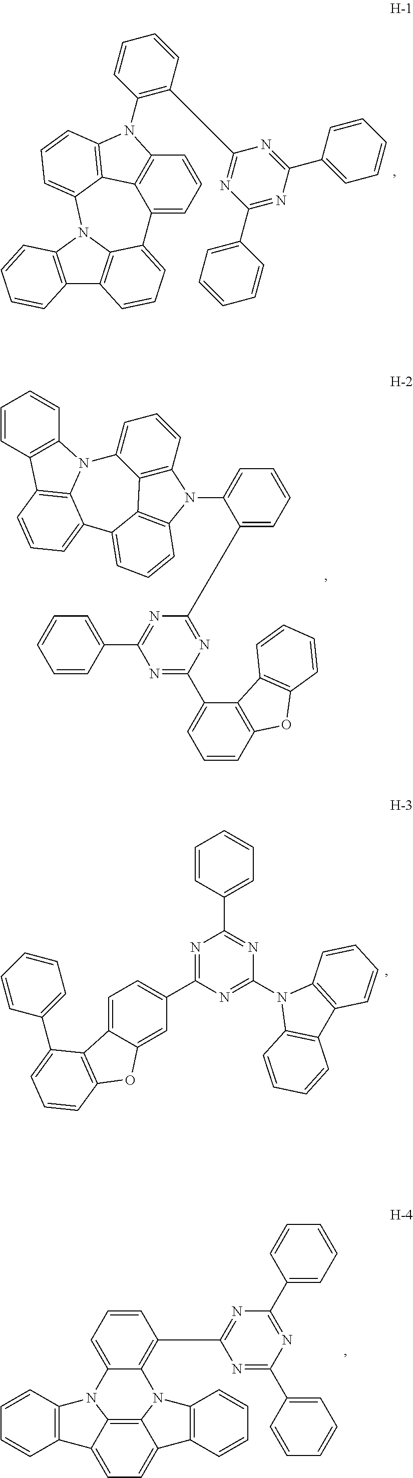 [SMILES: c1ccc(-c2nc(-c3ccccc3)nc(-c3ccccc3-n3c4cccc5c6cccc7c8ccccc8n(c8cccc3c8c54)c67)n2)cc1 ; c1ccc(-c2nc(-c3ccccc3-n3c4cccc5c6cccc7c8ccccc8n(c8cccc3c8c54)c67)nc(-c3cccc4oc5ccccc5c34)n2)cc1 ; c1ccc(-c2nc(-c3ccc4c(c3)oc3cccc(-c5ccccc5)c34)nc(-n3c4ccccc4c4ccccc43)n2)cc1 ; c1ccc(-c2nc(-c3ccccc3)nc(-c3cccc4c3n3c5ccccc5c5ccc6c7ccccc7n4c6c53)n2)cc1]

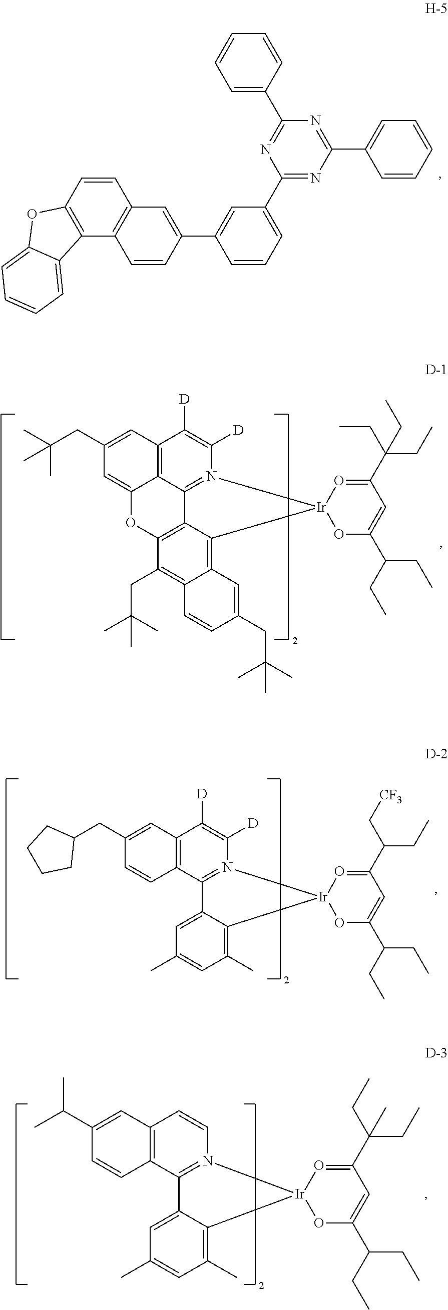

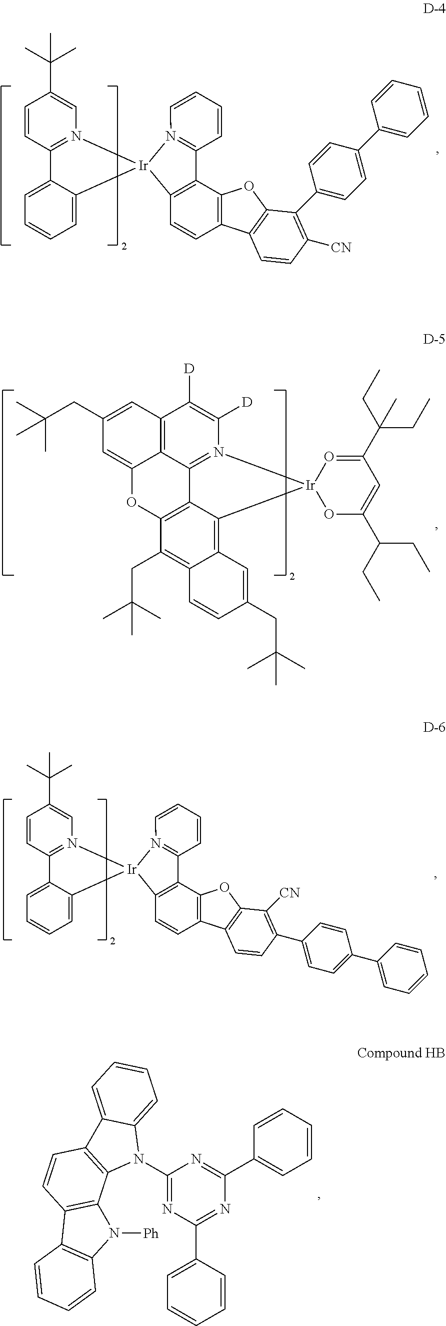

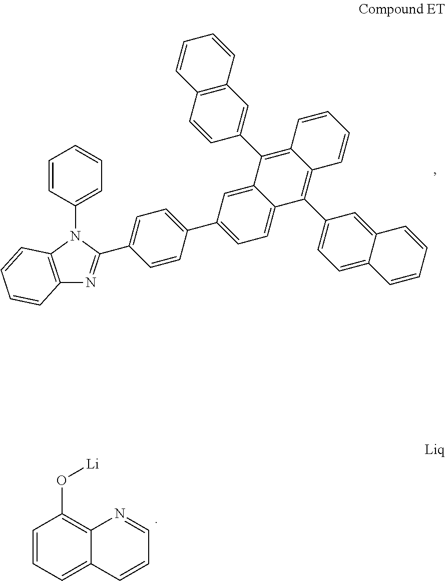

EQEₘₐₓ, EQE₂, EQE₃ and peak wavelength λₘₐₓ of the devices were measured, and brightness L₁, L₂ and L₃ corresponding to EQEₘₐₓ, EQE₂ and EQE₃ were recorded, where the peak wavelength λₘₐₓ was a maximum emission wavelength of the device at the brightness L₃. The data was recorded and shown in Table 2.

TABLE 2
Device data in Examples 1 to 5 and Comparative Examples 1 to 7

| | EQEₘₐₓ | EQE₂ | EQE₃ | λₘₐₓ | L₁ | L₂ | L₃ | |
|---|---|---|---|---|---|---|---|---|
| No. | (%) | (%) | (%) | (nm) | (cd/m²) | (cd/m²) | (cd/m²) | r |
| Example 1 | 30.3 | 27.0 | 30.0 | 620 | 3,000 | 10,000 | 5,000 | 0.99 |
| Example 2 | 27.0 | 24.3 | 25.1 | 621 | 2,200 | 8,000 | 5,000 | 0.93 |
| Example 3 | 28.0 | 25.2 | 26.2 | 625 | 120 | 8,000 | 5,000 | 0.94 |
| Example 4 | 33.5 | 30.2 | 33.1 | 620 | 3,500 | 12,000 | 5,000 | 0.99 |
| Example 5 | 28.1 | 25.3 | 25.7 | 532 | 1210 | 15,000 | 11,500 | 0.92 |
| Comparative | 41.0 | 36.9 | 34.0 | 620 | 500 | 1,400 | 5,000 | 0.83 |
| Example 1 | | | | | | | | |
| Comparative | 36.0 | 32.4 | 32.5 | 620 | 1,000 | 4,000 | 5,000 | 0.90 |
| Example 2 | | | | | | | | |
| Comparative | 28.4 | 25.6 | 24.2 | 621 | 272 | 3,000 | 5,000 | 0.85 |
| Example 3 | | | | | | | | |
| Comparative | 27.0 | 24.3 | 23.6 | 621 | 390 | 3,500 | 5,000 | 0.87 |
| Example 4 | | | | | | | | |
| Comparative | 15.0 | 13.5 | 7.9 | 625 | 19 | 150 | 5,000 | 0.53 |
| Example 5 | | | | | | | | |
| Comparative | 25.0 | 22.5 | 17.6 | 625 | 45 | 650 | 5,000 | 0.70 |
| Example 6 | | | | | | | | |
| Comparative | 26.2 | 23.6 | 18.8 | 536 | 274 | 1,700 | 11,500 | 0.72 |
| Example 7 | | | | | | | | |

Discussion

1. Carrier injection, especially hole injection, is adjusted.

Conductivity of HILs with different material compositions was measured. The measurement results are shown in Table 3.

TABLE 3
Conductivity of different HILs

| HIL No. | Material Composition | σ [10⁻⁵ S/m] |
|---|---|---|
| HIL-1 | HT1:HI3 (3%) | 179 |
| HIL-2 | HT1:HI1 (3%) | 24 |
| HIL-3 | HT1:HI1 (10%) | 48 |
| HIL-4 | HT1:HI1 (23%) | 80 |

When the doping proportions of HI3 and HI1 are both 3%, the conductivity of HIL-1 reaches 179×10⁻⁵ S/m, while the conductivity of HIL-2 is only 24×10⁻⁵ S/m. Since each of the peak wavelengths λₘₐₓ of Example 1 and Comparative Examples 1 to 3 is between 600 to 700 nm, the brightness L₃ is selected to be 5000 cd/m², and roll-off coefficients of Example 1 and Comparative Examples 1 to 3 are calculated according to a roll-off efficiency formula. The roll-off coefficients r of Comparative Examples 1 and 3 are only 0.83 and 0.85, respectively, which are both less than 0.91. The reason is that the conductivity of the HIL doped with the commercially available material HI3 in Comparative Example 3 is too high (179×10⁻⁵ S/m), resulting in excessive hole injection, thereby resulting in serious roll-off of the device, while the doping proportion of HI1 in the HIL in Comparative Example 1 is 3%, resulting in too low a conductivity (24×10⁻⁵ S/m) and insufficient hole injection, thereby resulting in relatively serious roll-off of the device as well. Therefore, it is a very significant direction to adjust and suppress the roll-off of the device through the doping proportion of the p-type doped material in the HIL. The conductivity of HI1 may be relatively low so that there is more room for the adjustment of the conductivity of HI1, that is, a hole injection ability is adjusted through the adjustment of a doping concentration so that carriers in the emissive layer are further balanced. For example, when the doping proportion of HI′ is increased to 10%, the conductivity of HIL-3 (the HIL in Comparative Example 2) is 48×10⁻⁵ S/m, and when the doping proportion of HI1 is increased to 23%, the conductivity of HIL-4 (the HIL in Example 1) is 80×10⁻⁵ S/m. The increase in conductivity indicates that more holes are injected into the device. However, it is obvious that only when the conductivity of the HIL is within an appropriate range can the injected holes and electrons be balanced to some extent and can the roll-off of the device efficiency be effectively suppressed.

In Example 1, the doping proportion of HI1 is 23%, EQEₘₐₓ of the device is 30%, and the brightness corresponding to EQEₘₐₓ reaches 3,500 cd/m². When EQE₂ is 27%, the brightness of the device reaches 10,000 cd/m², and r reaches 0.99, which is very close to 1, indicating that when the brightness of Example 1 is significantly increased from 3,500 cd/m² to 5,000 cd/m², the EQE has substantially no decay. Compared with Comparative Examples 1 and 2, the roll-off phenomenon of the device in Example 1 is significantly suppressed. It indicates that only when the conductivity of the HIL is within an appropriate range, for example, 50×10⁻⁵ S/m to 140×10⁻⁵ S/m, can the injected holes and electrons be better balanced to some extent and can the roll-off of the device efficiency be effectively suppressed.

FIG. 3 illustrates a trend that normalized EQE varies with the variation in L. As can be visually seen from FIG. 3, as the doping proportion of HI1 is increased, a position where the EQE starts to decrease moves toward a direction of high brightness, which indicates that adjusting the proportion of p-dopant (for Example 1, HT1 is p-dopant) in the HIL can more reasonably control the number of holes entering the emissive layer, thereby effectively increasing a ratio of exciton recombination, reducing the quenching of excitons and reducing the roll-off of the phosphorescent light-emitting device at high brightness.

Further, through the addition of structures of probe layers to the devices, the distribution of exciton recombination zones in Example 1, Comparative Example 1, and Comparative Example 2 are researched.

Methods for preparing Devices 1 to 5 where the structures of the probe layers are added at positions of different d of the device in Example 1 are described below.

The preparation method of Device 1 (d=0 nm) was the same as that in Example 1, except that a thin probe layer was additionally deposited on the EBL, and then the emissive layer was deposited, where a red light host material H-2 and a deep red luminescent material DRD were co-deposited to form the probe layer, DRD had a doping proportion of 1%, and the probe layer had a thickness of 20 Å.

The preparation method of Device 2 (d=10 nm) was the same as that in Example 1, except that an emissive layer with a thickness of 100 Å was deposited, a probe layer with a thickness of 20 Å was deposited, and then an emissive layer with a thickness of 300 Å was deposited. A red light host material H-2 and a deep red luminescent material DRD were co-deposited to form the probe layer, and DRD had a doping proportion of 1%.

The preparation method of Device 3 (d=20 nm) was the same as that in Example 1, except that an emissive layer with a thickness of 200 Å was deposited, a probe layer with a thickness of 20 Å was deposited, and then an emissive layer with a thickness of 200 Å was deposited. A red light host material H-2 and a deep red luminescent material DRD were co-deposited to form the probe layer, and DRD had a doping proportion of 1%.

The preparation method of Device 4 (d=30 nm) was the same as that in Example 1, except that an emissive layer with a thickness of 300 Å was deposited, a probe layer with a thickness of 20 Å was deposited, and then an emissive layer with a thickness of 100 Å was deposited. A red light host material H-2 and a deep red luminescent material DRD were co-deposited to form the probe layer, and DRD had a doping proportion of 1%.

The preparation method of Device 5 (d=40 nm) was the same as that in Example 1, except that a probe layer with a thickness of 20 Å was additionally deposited on the emissive layer, and then HBL was deposited. A red light host material H-2 and a deep red luminescent material DRD were co-deposited to form the probe layer, and DRD had a doping proportion of 1%.

In a similar manner, Devices 11 to 15 where the structures of the probe layers are added at positions of different d of the device in Comparative Example 1 and Devices 21 to 25 where the structures of the probe layers are added at positions of different d of the device in Comparative Example 2 were prepared, respectively.

Then, the EL spectra of the Devices 1 to 5, 11 to 15 and 21 to 25 were measured, and exciton fractions of Example 1, Comparative Example 1 and Comparative Example 2 were calculated. FIG. 2 illustrates the exciton fractions of Example 1, Comparative Example 1 and Comparative Example 2 with d of 0 nm, 10 nm, 20 nm, 30 nm and 40 nm, respectively, at the brightness (L₁) corresponding to EQEₘₐₓ The exciton fraction of Comparative Example 1 reaches a peak value at d=0 nm, which means that more excitons are distributed at an interface between the EBL and the EML. Compared with Comparative Example 1, the exciton fraction of Comparative Example 2 is significantly decreased at d=0 nm, and a peak value of the exciton distribution is located at about d=10 nm, indicating that the exciton distribution moves toward a direction of the cathode with the increase of the concentration of p-dopant and concentrated exciton distribution is improved. In Example 1, the concentration of p-dopant is further increased, the exciton distribution at d=0 nm is further decreased, and a peak value is reached at d=10 nm, where d=10 nm is exactly 25% of the thickness (40 nm) of the emissive layer. In conjunction with device performance, it can be seen that in Comparative Example 1, since the exciton distribution is not balanced and more excitons are distributed at the interface between the EBL and the EML, although the peak value of the EQE of the device reaches more than 40% at low brightness, after the brightness increases (the injected carriers increase), too narrow exciton distribution causes serious quenching, and since the excitons are close to the interface, the excitons are also easily affected by an interface defect. Therefore, the device has very serious efficiency roll-off and relatively low brightness and cannot be used for practical production. The peak value of the exciton distribution of Comparative Example 2 starts to be far away from the interface between the EBL and the EML so that the roll-off of the device is improved to some extent, where r is increased to 0.90 but still less than 0.91, and L₂ reaches only 4,000 cd/m², which is less than 5,000 cd/m². In conjunction with r and L₂, it can be seen that the roll-off of Comparative Example 2 is still relatively serious and the exciton distribution does not reach a best state. Through the adjustment of the proportion of p-dopant, the exciton distribution of Example 1 is improved, and a peak value of excitons is located at 50% of the thickness of the emissive layer and close to the anode, preferably, at 30% of the thickness of the emissive layer and close to the anode, more preferably, at 25% of the thickness of the emissive layer and close to the anode. From the point of view of the device performance, although EQEₘₐₓ of Example 1 is not as good as that of Comparative Examples 1 and 2, L₂ of Example 1 reaches 10,000 cd/m², and the roll-off coefficient reaches 0.99. Since the exciton distribution of Example 1 is wider and the peak value is farther away from the interface than those of Comparative Example 1, not only high efficiency can be maintained, but also the roll-off of the device is significantly improved and the lifetime is improved.

2. A luminescent material with an exciton lifetime of less than 2 microseconds is used for reducing the probability of exciton quenching.

An effect of the exciton lifetime on the roll-off of the device was researched in red and green light systems, respectively. Exciton lifetimes of two red light doped materials D-2 and D-5 and exciton lifetimes of two green light doped materials D-4 and D-6 are shown in Table 4.

TABLE 4
Exciton lifetimes of luminescent materials

| Luminescent | Exciton Lifetime |
|---|---|
| Material | (Microseconds) |
| D-2 | 1.04 |
| D-5 | 3.50 |
| D-4 | 1.7 |
| D-6 | 6.0 |

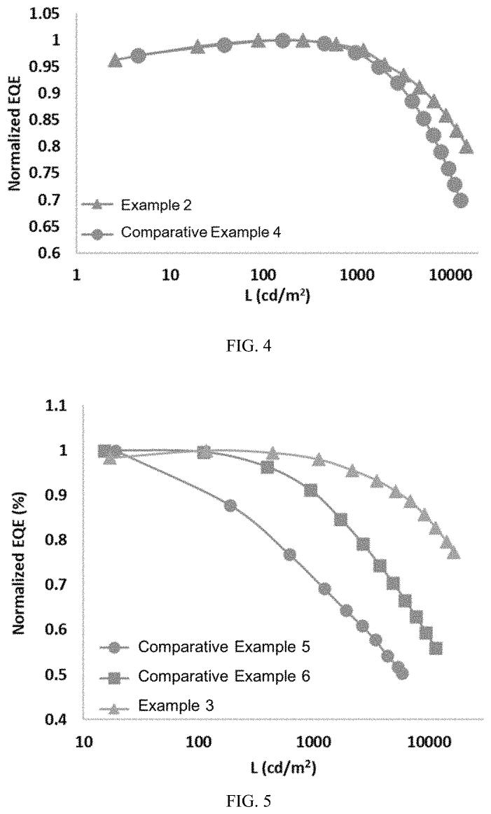

Example 2 differs from Comparative Example 4 in that the two red light luminescent materials D-2 and D-5 are used, and peak wavelengths of D-2 and D-5 are both between 600 to 700 nm, except that, as shown in Table 3, D-2 has an extremely short exciton lifetime which is far less than 2 microseconds so that the probability of exciton quenching can be effectively reduced, thereby suppressing the roll-off, while an exciton lifetime of D-5, which is 3.4 times the exciton lifetime of D-2, reaches 3.5 microseconds, but the exciton lifetime is too long to effectively suppress the roll-off. This is also confirmed by the comparison of the data of Example 2 and Comparative Example 4. Although EQEₘₐₓ of both Example 2 and Comparative Example 4 is 27%, L₁ of Example 2 reaches 2,200 cd/m², while L₁ of Comparative Example 4 is only 390 cd/m². When EQE₂ is 24.3%, L₂ of Example 2 reaches 8,000 cd/m², and r is 0.93, which is greater than 0.91, while r of Comparative Example 4 is only 0.87, which is 6% less than r of Example 2. Significant roll-off indicates that using the luminescent material with an exciton lifetime of less than 2 microseconds effectively suppresses the roll-off of the device. Also, as can be visually seen from FIG. 4, the EQE varies with the variation in L. After the brightness is increased to some extent, the efficiency roll-off of Example 2 is less than that of Comparative Example 4. Therefore, reducing the exciton lifetime of the luminescent material can effectively reduce the efficiency roll-off of the device.

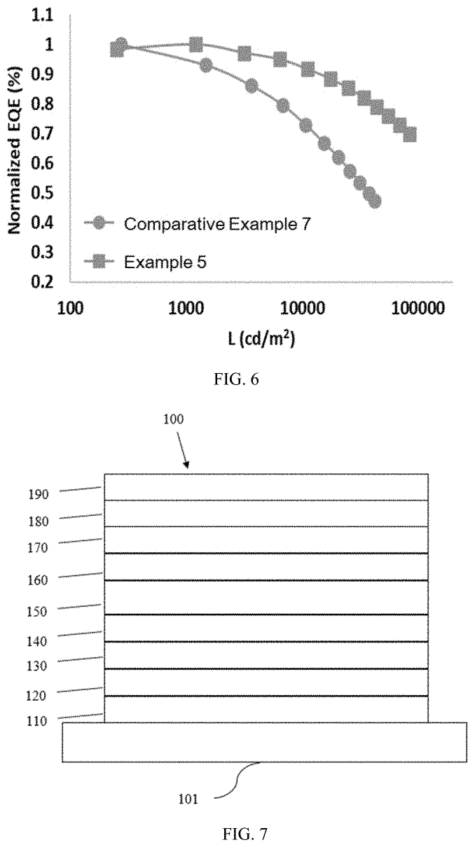

The peak wavelengths of Example 5 and Comparative Example 7 are both between 500 nm to 600 nm. D-4 has an exciton lifetime less than 2 microseconds, while an exciton lifetime of D-6 reaches 6.0 microseconds, which is too long to effectively suppress the roll-off. It can also be seen from the device data that although both Example 5 and Comparative Example 7 have EQEₘₐₓ of more than 26%, L₂ of Comparative Example 7 is only 1700 cd/m², which is far less than 5000 cd/m², indicating that the device efficiency of Comparative Example 7 significantly decays from relatively low brightness with a significant roll-off effect, while L₂ of Example 5 reaches ultra-high brightness of 15000, and the roll-off coefficient r also reaches 0.92, while the roll-off coefficient r of Comparative Example 7 is only 0.72. Also, as can be visually seen from FIG. 6, the decrease in EQE of Example 5 is much less than that of Comparative Example 7 with the increase of the brightness.

In summary, using the material with an exciton lifetime of less than 2 microseconds can effectively suppress the roll-off of the device in both the red and green light systems.

3. A host material with an appropriate triplet energy level is selected for a combination with the luminescent material.

Table 5 shows the triplet energy levels T₁ of the host materials H-4, H-5 and H-2 and the luminescent material D3:

TABLE 5
Data of triplet energy levels T₁

| Material | | |
|---|---|---|
| No. | T₁ (eV) | ΔT₁ = T_{1-RH} − T_{1-RD} (eV) |
| H-4 | 2.16 | 0.17 |
| H-5 | 2.27 | 0.28 |
| H-2 | 2.59 | 0.6 |
| D-3 | 1.99 | / |

As can be seen from Table 5, the triplet energy levels of the host compounds H-4 and H-5 selected in Comparative Examples 5 and 6 are both relatively low, which are 2.16 eV and 2.27 eV, respectively, and differences between the triplet energy levels of the host compounds H-4 and H-5 and T₁ of D-3 are only 0.17 eV and 0.28 eV. With a small energy level difference, reverse transfer of energy from a guest to a host is easy to occur. While, the triplet energy level of the host compound H-2 used in Example 3 reaches 2.59 eV, and a difference between the triplet energy level of the host compound H-2 and the triplet energy level of D-3 reaches 0.6 eV. With a large energy level difference, the reverse transfer of energy from the guest to the host is difficult to occur.

In conjunction with the analysis on the device performance in Table 2, it can be seen that the peak wavelengths λₘₐₓ of Example 3, Comparative Example 5 and Comparative Example 6 are all between 600 to 700 nm, L₃ is selected to be 5000 cd/m², and r calculated according to the roll-off efficiency formula is 0.94, 0.53 and 0.70, respectively. Apparently, the example using ΔT₁ of less than 0.3 eV has larger r and smaller roll-off of the device. L₂ of Example 3 even reaches high brightness of 8,000 cd/m² with high EQEₘₐₓ of 28%. Compared with Comparative Examples 5 and 6, Example 3 has very significant advantages in absolute efficiency and low roll-off effect. Also, as can be visually seen from FIG. 5, the efficiency roll-off of Comparative Example 5 is very serious, basically exhibiting a linear decrease. Although EQEₘₐₓ of Comparative Example 6 reaches 25% at L₁=1,100 cd/m², the peak value of the EQE is not very high, and when the EQE is decreased to 22.5%, L₂ is increased to only 1,200 cd/m². With significant efficiency decay at relatively low brightness, r is only 0.70, and the roll-off effect is also very significant. Also, as can be visually seen from FIG. 5, the roll-off of Comparative Example 6 is still very serious.

In Example 4, the structure of the HIL was modified. The emissive layer was composed of D-2 with a short exciton lifetime in combination with the host material H-2 with a high triplet energy level (related parameters of D-2 and H-2 are shown in Table 6).

TABLE 6
Related parameters of D-2 and H-2

| Material | | ΔT₁ = T_{1-RH} − T_{1-RD} | Exciton Lifetime |
|---|---|---|---|
| No. | T₁ (eV) | (eV) | (Microseconds) |
| H-2 | 2.59 | 0.59 | / |
| D-2 | 2.00 | / | 1.04 |

From the device data of Example 4 shown in Table 2, it can be seen that EQEₘₐₓ of Example 4 reaches 33.5%, the roll-off coefficient, like that of Example 1, reaches an ultra-high level of 0.99, and L₂ of Example 4 is further increased to 12,000 cd/m², which is increased up to 20% higher than 10,000 cd/m² of Example 1. This type of device with high brightness and low roll-off is exactly an intention of the present disclosure. It indicates that using the combination of the above three schemes can further reduce the roll-off of the device, which has an unexpected effect in suppressing the roll-off of the device.

It is to be understood that various embodiments described herein are merely illustrative and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limiting.

What is claimed is:

1. An organic electroluminescent device, which is a bottom-emitting single-layer device, comprising an anode, a cathode and at least one emissive layer disposed between the anode and the cathode, wherein the at least one emissive layer comprises at least one luminescent material;
when brightness is L₁, the organic electroluminescent device has maximum external quantum efficiency EQEₘₐₓ, wherein the EQEₘₐₓ≥26%;
when the brightness is L₂, the organic electroluminescent device has external quantum efficiency EQE₂, wherein EQE₂/EQEₘₐₓ=90%, L₁<L₂, and L₂>5000 cd/m²;
when the brightness is L₃, the organic electroluminescent device has external quantum efficiency EQE₃ and a roll-off coefficient r=EQE₃/EQEₘₐₓ, wherein the roll-off coefficient r≥0.91; and
the at least one luminescent material has a peak wavelength λₘₐₓ, wherein 500 nm<λₘₐₓ<700 nm; when 600 nm<λₘₐₓ<700 nm, the brightness L₃=5000 cd/m², and when 500 nm<λₘₐₓ<600 nm, the brightness L₃=11500 cd/m².

2. The organic electroluminescent device according to claim 1, wherein the EQEₘₐₓ≥27%; preferably, the EQEₘₐₓ≥28%.

3. The organic electroluminescent device according to claim 1, wherein the L₂≥6000 cd/m²; preferably, the L₂≥7000 cd/m².

4. The organic electroluminescent device according to claim 1, wherein the device comprises a hole injection layer (HIL) having a conductivity of greater than 50×10⁻⁵ S/m and less than 140×10⁻⁵ S/m; preferably, the HIL has a conductivity of greater than 60×10⁻⁵ S/m and less than 120×10⁻⁵ S/m.

5. The organic electroluminescent device according to claim 1, wherein when the organic electroluminescent device reaches EQEₘₐₓ, the exciton recombination zone is located in the emissive layer on the side close to the anode within a region of less than 50% of the emissive layer thickness; preferably, when the organic electroluminescent device reaches EQEₘₐₓ, the exciton recombination zone is located in the emissive layer on the side close to the anode within a region of less than 30% of the emissive layer thickness; more preferably, when the organic electroluminescent device reaches EQEₘₐₓ, the exciton recombination zone is located in the emissive layer on the side close to the anode within a region of less than 25% of the emissive layer thickness.

6. The organic electroluminescent device according to claim 1, wherein the at least one luminescent material has an exciton lifetime of less than 2 microseconds; preferably, the at least one luminescent material has an exciton lifetime of less than 1.5 microseconds.

7. The organic electroluminescent device according to claim 1, wherein the at least one emissive layer further comprises at least one host material, wherein a difference between a triplet energy level of the at least one host material and a triplet energy level of the at least one luminescent material is ΔT₁, and the ΔT₁≥0.3 eV; preferably, the ΔT₁≥0.4 eV; more preferably, the ΔT₁≥0.5 eV.

8. The organic electroluminescent device according to claim 1, wherein the roll-off coefficient r≥0.95; preferably, the roll-off coefficient r≥0.97.

9. The organic electroluminescent device according to claim 1, wherein the at least one luminescent material is a phosphorescent material.
